(19) United States
(12) Patent Application Publication
(10) Pub. No.: US 2016/0207776 A1
(43) Pub. Date: Jul. 21, 2016

(54) PURIFICATION PROCESS FOR GRAPHENE NANORIBBONS

(71) Applicant: BASF SE, Ludwigshafen (DE)

(72) Inventors: Tobias Hintermann, Therwil (CH); Matthias Georg Schwab, Mannheim (DE); Kitty Chih-Pei Cha, Ludwigshafen (DE); Thomas Weitz, Mannheim (DE); Ansgar Schäfer, Karlsruhe (DE); Imke Britta Müller, Heidelberg (DE)

(21) Appl. No.: 14/914,558

(22) PCT Filed: Aug. 25, 2014
(86) PCT No.: PCT/EP2014/068007

§ 371 Date: Feb. 25, 2016

(30) Foreign Application Priority Data
Sep. 4, 2013 (EP) 13182933.5
May 16, 2014 (EP) 14168687.3

(51) Int. Cl. C01B 31/04; H01L 29/16; H01L 29/78; H01L 29/06

(52) U.S. Cl. CPC C01B 31/0492; H01L 29/0669; H01L 29/1606; H01L 29/78

(57) ABSTRACT

In a process for purifying graphene nanoribbons, a composition comprising graphene nanoribbons GNR1 and at least one contaminant is brought into contact with a liquid medium that includes a dispersant. The graphene nanoribbons GNR1 are dispersed in the liquid medium so as to obtain a liquid dispersion of the graphene nanoribbons GNR1. The liquid dispersion of the graphene nanoribbons GNR1 is subjected to a separation treatment so as to at least partly remove the at least one contaminant, thereby obtaining a liquid dispersion of purified graphene nanoribbons GNR1.

The present invention relates to a purification method for graphene nanoribbons and to a liquid dispersion comprising purified graphene nanoribbons.

Graphene, an atomically thin layer from graphite, has received considerable interest in physics, material science and chemistry since the recent discovery of its appealing electronic properties. These involve superior charge carrier mobility and the quantum Hall effect. Moreover, its chemical robustness and material strength make graphene an ideal candidate for applications ranging from transparent conductive electrodes to devices for charge and energy storage.

Graphene nanoribbons (GNRs) are promising building blocks for composite materials and novel graphene based electronic devices. Beyond the most important distinction between metallic zig-zag edge (ZGNR) with interesting electron spin properties and predominantly semiconducting armchair edge ribbons (AGNR), more general variations of the geometry of a GNR allow for gap tuning through one-dimensional (1D) quantum confinement. In general, increasing the ribbon width leads to an overall decrease of the band gap, with superimposed oscillation features that are maximized for armchair GNRs (AGNRs).

Graphene nanoribbons are one dimensional (linear) structures that are derived from the parent two dimensional graphene lattice. Their characteristic feature is high shape-anisotropy due to the increased length to width ratio. The structural basis of GNRs is a hexagonal sp² hybridized carbon network which is terminated at the edges either by hydrogen atoms or any other organic or inorganic substituent. Currently, their usage in yet smaller, flatter and faster carbon-based devices and integrated circuits is being widely discussed in materials science.

Standard top-down fabrication techniques of GNR such as cutting graphene sheets e.g. using lithography, unzipping of carbon nanotubes (e.g. described in US2010/0047154 and US2011/0097258), or using nanowires as a template (e.g. described in KR2011/005436) are not suitable for ribbons narrower than 5-10 nm, because the edge configuration is not precisely controlled and they do not yield ribbons with a monodisperse width distribution. For high-efficiency electronic devices, the width of the ribbons need to be narrower than 10 nm, their width needs to be precisely controlled and, importantly, their edges need to be smooth because even minute deviations from the ideal edge shapes seriously degrade the electronic properties.

Due to the inherent limitations of lithographic methods and of other known approaches to fabricate graphene nanostructures, however, the experimental realization of GNRs with the required high precision has remained elusive. Bottom-up approaches based on cyclodehydrogenation reactions in solution (e.g. Dossel, L.; Gherghel, L.; Feng, X.; Müllen, K. Angew. Chem. Int. Ed. 50, 2540-2543 (2011)) or on solid substrates (e.g. Cai, J.; et al. Nature 466, 470-473 (2010)) have recently emerged as promising routes to the synthesis of nanoribbons and nanographenes with precisely controlled structures.

At least two general types of precisely controlled linear nanoribbon structures can be distinguished. In a first type, the edges are forming a straight line along the nanoribbon, while in another type, sometimes called ‘chevron’ type or ‘graphitic nanowiggles’ (described e.g. in Phys. Rev. Lett. 2011 (107), 135501), the edges are lying on a corrugated or saw-toothed line. The latter case can also be described as a periodic repetition of nonaligned graphitic nanoribbon domains seamlessly stitched together without structural defects.

The edges of the graphene nanoribbons may be substituted either with hydrogen atoms and/or with any other organic or inorganic groups.

In solution-based approaches starting from oligophenylene precursors, a polymer is typically prepared in a first step which is subsequently converted into the graphitic structure, e.g. by Scholl-type oxidative cyclodehydrogenation.

J. Wu, L. Gherghel, D. Watson, J. Li, Z. Wang, C. D. Simpson, U. Kolb, and K. Müllen, Macromolecules 2003, 36, 7082-7089 report the synthesis of graphitic nanoribbons obtained by oxidative cyclodehydrogenation of soluble branched polyphenylenes. Y. Fogel, L. Zhi, A. Rouhanipour, D. Andrienko, H. J. Räder, and K. Müllen, Macromolecules 2009, 42, 6878-6884 report the synthesis of a homologous series of five monodisperse ribbon-type polyphenylenes, with rigid dibenzopyrene cores in the repeat units, by microwave-assisted Diels-Alder reaction. The size of the obtained polyphenylene ribbons ranges from 132 to 372 carbon atoms in the aromatic backbone which incorporates up to six dibenzopyrene units. M. G. Schwab et al. (J. Am. Chem. Soc. 2012, 134, 18169) have prepared structurally defined GNRs with high lateral extension by Yamamoto type polycondensation followed by cyclodehydrogenation and WO2012/149257 describes the synthesis of structurally controlled GNR via poly(phenylene ethynylene) intermediates.

All these solution based methods have so far only led to poorly soluble and hardly dispersible agglomerates of graphene nanoribbons which prevents efficient purification and processing of the graphene ribbons, e.g. for incorporation into electronic devices or composite materials. Typically, after cyclodehydrogenation the graphene nanoribbons precipitate from the solvent they were prepared in and can be collected as a black, graphitic bulk material.

In KR101082335B, the preparation of a structurally controlled GNR and the use of the material for the fabrication of a thin film transistor by aerosol jet printing technology are described. However purification of the GNR material is not reported and the solubility of the GNR is low (0.2 wt % in THF).

GNR compositions in organic solvents have also been described by M. G. Schwab et al. (J. Am. Chem. Soc. 2012, 134, 18169) for measuring UV/vis spectra of controlled bottom-up graphene nanoribbons.

A surface-confined (also referred to as “surface-assisted”) bottom-up approach to controlled graphene nanoribbons has been described in J. Cai et al., Nature 466, pp. 470-473 (2010) and in number of publications since then (e.g. S. Blankenburg et al., ACS Nano 2012, 6, 2020; S. Linden et al., Phys. Rev. Lett. 2012, 108, 216801). However, it was not reported that these graphenene nanoribbons being present on the metal surface on which they were prepared might be subjected to any further treatment such as a purification or dispersion treatment.

As mentioned above, graphene nanoribbons are promising building blocks for novel graphene based electronic devices. For these applications, the graphene nanoribbons need to be of high purity. However, in the presently known preparation methods, contaminants are produced as well. So, any as-synthesized GNR composition inevitably contains contaminants which need to be removed before using the purified GNR composition in an electronic device manufacturing process.

Typically, in an electronic device (e.g. a field-effect transistor containing graphene nanoribbons, also referred to as “GNR-FET”) manufacturing process, graphene nanoribbons are deposited on a substrate (such as a coated Si wafer). Preferably, the graphene nanoribbons deposited on the substrate should provide a uniform and flat structure. Apart from high purity (i.e. no contaminants which may disrupt the uniform structure), this typically means that any uncontrolled aggregation of graphene nanoribbons (e.g. individual graphene nanoribbons sticking together and thereby forming GNR bundles of undefined structure) should be suppressed as much as possible. It would be beneficial to have graphene nanoribbons which have been purified from contaminants and are present in individualized form (i.e. no uncontrolled aggregation of single graphene nanoribbons) and remain in such an individualized form when applied onto a substrate.

The preparation of a GNR-FET containing graphene nanoribbons which have been prepared by a chemical bottom-up synthesis is described by P. Bennett, Appl. Phys. Lett. 103, 253114 (2013). On a Au substrate, a plurality of entangled graphene nanoribbons are prepared and these entangled graphene nanoribbons are subsequently transferred to another substrate on which a drain electrode and a source electrode are applied by lithography.

US 2011/0244661 A1 discloses the preparation of graphene nanoribbons by unzipping carbon nanotubes. From these graphene nanoribbons, a FET-like device was prepared. However, as already discussed above, when using a non-bottom-up approach, the edge configuration is not precisely controlled and does not yield in nanoribbons with a monodisperse width distribution. For high-efficiency electronic devices, the GNR width needs to be precisely controlled on an atomic level and, importantly, GNR edges need to be smooth because even minute deviations from the ideal edge shapes seriously degrade the electronic properties.

Thus, it still remains a challenge to prepare devices such as electronic, optoelectronic and optical devices (e.g. field-effect transistors) which comprise GNRs prepared by a bottom-up synthesis (i.e. GNRs having a well-defined structure even on the atomic level) and wherein these “bottom-up synthesized” GNRs together with other relevant parts of the device (such as drain and source electrodes in a FET) are arranged in a well-defined manner (e.g. just a single GNR connecting both electrodes instead of a bundle of randomly orientated GNRs).

It is an object of the present invention to provide a purification method for graphene nanoribbons which is easy to perform and results in purified graphene nanoribbons that can be deposited on a substrate in a controlled and well-defined manner. It is also an object of the present invention to provide a device wherein graphene nanoribbons of very high structural uniformity are arranged together with other relevant parts of the device (such as drain and source and gate electrodes of a transistor) in a well-defined manner.

According to a first aspect of the present invention, the object is solved by a process for purifying graphene nanoribbons, which comprises
bringing into contact a composition comprising graphene nanoribbons GNR1 and one or more contaminants with a liquid medium comprising a dispersant, and dispersing the graphene nanoribbons GNR1 in the liquid medium so as to obtain a liquid dispersion of the graphene nanoribbons GNR1,
subjecting the liquid dispersion of the graphene nanoribbons GNR1 to a separation treatment so as to at least partly remove the one or more contaminants, thereby obtaining a liquid dispersion of purified graphene nanoribbons GNR1.

In the present invention, it has been realized that there is a strong interaction between graphene nanoribbons and dispersants which can be used not only for stabilizing the graphene nanoribbons in a liquid (preferably aqueous) medium but also for separating the graphene nanoribbons from undesired contaminants which may result from the graphene nanoribbon preparation method. The one or more contaminants are either not sufficiently interacting with the dispersant(s) for getting dispersed, or show a level of interaction with the dispersant(s) which is different from the level of interaction between the graphene nanoribbons GNR1 and the dispersant(s). This different level of interaction makes it possible to separate the contaminants and obtain a dispersion of purified graphene nanoribbons GNR1.

In the present invention, the term “graphene nanoribbons” is used according to its commonly accepted meaning and therefore relates to one dimensional (linear) structures that are derived from the parent two dimensional graphene lattice. Their characteristic feature is high shape-anisotropy due to the increased length to width ratio. The structural basis of GNRs is a hexagonal sp² hybridized carbon network which is terminated at the edges either by hydrogen atoms or any other organic or inorganic substituent. Typically, the aromatic basal plane of graphene nanoribbons is in the form of a strip typically having a width of less than 50 nm or even less than 10 nm or even less than 5 nm (e.g. measured via scanning tunneling microscopy STM). Typically, the aspect ratio of graphene nanoribbons (i.e. ratio of length to width) is at least 10. Ideally, a graphene nanoribbon is a one-atom-thick layer material, i.e. a single-layer graphene nanoribbon (in other words: a graphene nanoribbon made of just one ribbon layer). However, the GNR may also be a few-layer graphene nanoribbon, e.g. up to 10 layers or up to 5 layers. Preferably, the GNR is a single-layer graphene nanoribbon.

In principle, the composition comprising the graphene nanoribbons GNR1 to be purified (i.e. the “target” graphene nanoribbons to be separated from other materials being present in the composition) can be provided by top-down preparation methods or bottom-up preparation methods. In both of these preparation methods, compositions are obtained which do not exclusively consist of the desired target graphene nanoribbons GNR1 but also contain contaminants.

Standard top-down fabrication techniques are known to the skilled person and include cutting graphene sheets e.g. using lithography, unzipping of carbon nanotubes (e.g. described in US2010/0047154), or using nanowires as a template (e.g. described in KR2011/005436).

By using bottom-up preparation methods, graphene nanoribbons of well-defined width and edge structure are obtainable, as known to the skilled person. In one of these bottom-up approaches, precursor molecules (such as polycyclic aromatic compounds or oligophenylene compounds) are provided and linked to each other so as to form a precursor polymer which is then subjected to a cyclodehydrogenation reaction, carried out either in solution or on solid substrates (i.e. surface-assisted cyclodehydrogenation), as described e.g. by Dossel, L.; Gherghel, L.; Feng, X.; Müllen, K. Angew. Chem. Int. Ed. 50, 2540-2543 (2011) and Cai, J.; et al. Nature 466, 470-473 (2010), WO 2013/093756 A1, and WO 2013/072292 A1. Similar to conventional polymers, the structure of such well-defined graphene nanoribbons obtained from specific precursor molecules can be described by a repeating unit.

At least two general types of precisely controlled linear nanoribbon structures can be distinguished. In a first type, the edges are forming a straight line along the nanoribbon, while in another type, sometimes called ‘chevron’ type or ‘graphitic nanowiggles’ (described e.g. in Phys. Rev. Lett. 2011 (107), 135501), the edges are lying on a corrugated or saw-toothed line. The latter case can also be described as a periodic repetition of nonaligned graphitic nanoribbon domains seamlessly stitched together without structural defects. Both types of graphene nanoribbons can be subjected to the purification method of the present invention.

It has been realized that the purification method of the present invention is in particular suitable for purifying graphene nanoribbons which have been prepared by a bottom-up preparation method and therefore have a well-defined structure (i.e. a structure that can be described by a repeating unit).

Accordingly, in a preferred embodiment, the composition comprising the graphene nanoribbons GNR1 has been obtained by a bottom-up preparation method.

Preferably, the graphene nanoribbons GNR1 comprise a repeating unit.

Preferably, the graphene nanoribbons GNR1 or at least a segment of each of these graphene nanoribbons are made of [RU]ₙ, wherein RU is a repeating unit and 2≦n≦2500.

Similar to conventional polymers, graphene nanoribbons of defined structure can have their specific repeating units. The term “repeating unit” relates to the part of the nanoribbon whose repetition would produce either the complete ribbon (except for the ends) or, if the GNR is made of two or more segments (i.e. similar to the blocks of a block copolymer), one of these segments (except for the ends). The term “repeating unit” presupposes that there is at least one repetition of said unit. In other words, if the repeating unit is referred to as RU, the GNR or one of its segments is made of n repeating units RU with n≧2 (i.e. (RU)ₙ with n≧2). The upper limit depends on the desired final properties of the graphene nanoribbon and/or the process conditions, and can be e.g. n≦2500.

The graphene nanoribbons GNR1 may comprise just one type of repeating unit RU or may comprise two or more segments or blocks, each segment or block being made of its specific repeating unit RU1, RU2, . . . etc. Segmented graphene nanoribbons are described e.g. in WO 2013/072292 A1.

Preferably, the composition comprises graphene nanoribbons GNR1 having a repeating unit which is derived from at least one substituted or unsubstituted polycyclic aromatic monomer compound, and/or from at least one substituted or unsubstituted oligophenylene aromatic monomer compound. As already mentioned above, the graphene nanoribbons GNR1 having a repeating unit are preferably obtained or obtainable by forming a precursor polymer from at least one polycyclic aromatic monomer compound and/or at least one oligophenylene aromatic monomer compound, followed by subjecting the precursor polymer to a cyclodehydrogenation. Such a bottom-up approach for preparing graphene nanoribbons is known to the skilled person, see references cited above.

The polycyclic aromatic monomer compound can be a polycyclic aromatic hydrocarbon monomer compound. Exemplary polycyclic aromatic hydrocarbon monomer compounds are disclosed e.g. in WO 2013/072292 A1.

Alternatively, the polycyclic aromatic monomer compound may comprise at least one heterocyclic ring, in particular two or more annelated aromatic rings and at least one of the annelated aromatic rings comprises one or more heteroatoms. By using such polycyclic aromatic monomer compounds which comprise at least one heterocyclic ring, graphene nanoribbons of defined structure having a heteroatomic substitution modification are obtainable. A heteroatomic substitution modification means the replacement of at least one carbon atom in the hexagonal sp² hybridized carbon network with at least one heteroatom or heteroatomic group. The substitution may be anywhere within the graphene hexagonal sp² hybridized carbon network. Exemplary heteroatoms or heteroatomic groups include e.g. nitrogen, boron, phosphor and its oxides, silicon, oxygen, sulphur and its oxides, hydrogen, or any combination thereof. Further details about such heteroatomic modified graphene nanoribbons are disclosed e.g. in EP 12 169 326 and in Angew. Chem., International Edition (2013), 52(16), 4422-4425.

The oligophenylene aromatic monomer compound can be an oligophenylene aromatic hydrocarbon monomer compound. Exemplary oligophenylene aromatic hydrocarbon monomer compounds are disclosed e.g. in WO 2013/072292 A1 and WO 2013/093756 A1.

Alternatively, the oligophenylene aromatic monomer compound may comprise at least one heterocyclic ring. By using such aromatic monomer compounds which comprise at least one heterocyclic ring, graphene nanoribbons of defined structure having a heteroatomic substitution modification are obtainable. Further details about such heteroatomic modified graphene nanoribbons are disclosed e.g. in EP 12 169 326 and in Angew. Chem., International Edition (2013), 52(16), 4422-4425.

So, the graphene nanoribbons GNR1 can be graphene nanoribbons having a repeating unit which comprises at least one heteroatomic substitution modification.

The graphene nanoribbons GNR1 may also be graphene nanoribbons having a repeating unit which comprises at least one vacancy modification. Further details about such graphene nanoribbons having well-defined vacancy modifications are disclosed e.g. in EP 12 169 326.

The composition comprising the graphene nanoribbons GNR1 can be an “as-synthesized” composition, i.e. a composition as directly obtained from the graphene nanoribbon preparation process without any post-treatment steps before being brought into contact with the liquid medium comprising a dispersant.

So, if the graphene nanoribbons are prepared by a solution-based process, said as-synthesized reaction solution may in principle be directly brought into contact with the liquid dispersant medium. If the graphene nanoribbons are prepared by a surface assisted process and therefore obtained on a substrate, it is possible to bring said as-synthesized assembly of substrate and graphene nanoribbons into contact with the liquid dispersant medium.

Alternatively, it may be preferred that the composition comprising the graphene nanoribbons GNR1 is subjected to a purification pre-treatment before being brought into contact with the liquid medium comprising a dispersant. In the purification pre-treatment, the amount of undesired contaminants is reduced to some extent so as to improve efficiency of the main purification step.

The purification pre-treatment may include commonly known purification steps such as filtration, chromatography, treatment with a solvent, preferably an organic solvent (e.g. for washing out contaminants), treatment with an acidic or basic solution, centrifugation, thermal treatment, electrophoresis, sedimentation, or any combination thereof.

The form of the GNR1-containing composition to be brought into contact with the liquid dispersant medium is not critical. The GNR1-containing composition can be provided e.g. as a powder composition, a liquid composition, a solid substrate with the graphene nanoribbons GNR1 being on the surface of the substrate, or combinations thereof.

As mentioned above, with the presently known graphene nanoribbon preparation methods, compositions are obtained which do not exclusively consist of the desired target graphene nanoribbons but also contain contaminants.

The term “contaminant” refers to those components of the GNR composition which have a structure and properties different from the “target” graphene nanoribbons GNR1 to be purified. Depending on the preparation method used, the kind of contaminants may vary. Typical contaminants of a graphene nanoribbon preparation method (e.g. a method preparing GNRs via cyclodehydrogenation, either in a solution-based process or a surface-assisted process) include non-reacted precursor molecules, non-reacted precursor polymers, polymeric reaction products having no graphene nanoribbon structure, agglomerates (e.g. agglomerated particles resulting in an agglomerate structure which is too large for being effectively dispersed), solid substrates, and/or metal residues (e.g. originating from the catalyst). In the GNR preparation method using surface-assisted cyclodehydrogenation of precursor polymers, the solid substrate on which the graphene nanoribbons GNR1 are provided represents a contaminant as well.

Typically, the contaminants are non-GNR-materials. However, the contaminants may also comprise graphene nanoribbons GNR2 which differ in at least one property from the graphene nanoribbons GNR1.

Similar to the graphene nanoribbons GNR1, the graphene nanoribbons GNR2 can be obtained either by top-down or bottom-up preparation methods. With regard to further details of these preparation methods, reference can be made to the statements made above when discussing preparation methods of GNR1.

Typically, the graphene nanoribbons GNR2 represent a by-product generated during the preparation of the graphene nanoribbons GNR1. Depending on the intended final application of the graphene nanoribbons GNR1 (e.g. in electronic devices), it might be preferred not only to remove the non-graphene nanoribbon contaminants but also graphene nanoribbon by-products having undesired properties in view of the intended final application.

However, in principle, it is also possible that the graphene nanoribbons GNR1 and GNR2 have been prepared in two separate processes and blended with each other at a later stage.

Similar to the graphene nanoribbons GNR1, the graphene nanoribbons GNR2 can have a well defined structure, i.e. a structure comprising a repeating unit RU.

The graphene nanoribbons GNR1 and GNR2 differ at least in one property, such as ribbon width, ribbon length, ribbon-edge-located substituents, degree of cyclodehydrogenation (thereby having different extensions of the aromatic system in the basal plane of the graphene nanoribbons), repeating unit, number of ribbon segments or ribbon blocks, heteroatomic substitution modification, vacancy modification, or any combination thereof.

As will be discussed below in further detail, the degree of interaction between the dispersant and the graphene nanoribbons GNR1 differs from the one between the dispersant and the graphene nanoribbons GNR2, which in turns makes it possible to at least partly separate the graphene nanoribbons GNR1 and GNR2 from each other and obtain a liquid dispersion of purified graphene nanoribbons GNR1.

The GNR1-containing composition is brought into contact with a liquid medium comprising a dispersant, and the graphene nanoribbons are dispersed in the liquid medium so as to obtain a liquid dispersion of purified graphene nanoribbons GNR1.

In the present invention, dispersants commonly known to the skilled person can be used. Based on his common general knowledge, the skilled person knows what kind of compounds are acting as a dispersant.

Appropriate liquids that can be used in combination with a specific dispersant are known to the skilled person. As an example, the liquid medium can be an aqueous medium which may optionally comprise a polar organic liquid such as an alcohol. So, in a preferred embodiment, the liquid medium is an aqueous medium. Alternatively, the liquid component can be an organic liquid, preferably a polar organic liquid such as an alcohol.

Depending on the properties of the graphene nanoribbons GNR1 and the type of dispersant, the weight ratio of graphene nanoribbons GNR1 to dispersant may vary over a broad range. The amount of dispersant needs to be high enough so as to sufficiently interact with the graphene nanoribbons GNR1 and disperse the graphene nanoribbons GNR1 in the liquid medium. Appropriate amounts of dispersant can be established by the skilled person on the basis of routine experimentation.

The invention provides purified graphene nanoribbons that are dispersed in solution, preferably singly dispersed, i.e. preferably as individualized dispersant-coated graphene nanoribbons. A number of dispersants may be used for this purpose wherein the dispersant is associated with the graphene nanoribbon by covalent or noncovalent means. The dispersant should preferably substantially cover the length of the nanoribbon, preferably at least half of the length of the nanoribbon, more preferably substantially all of the length. The dispersant can be associated in a periodic manner with the nanoribbon.

The dispersing agents are typically synthetic or naturally occurring detergents or any other composition capable of encapsulating and suitably solubilizing hydrophobic compounds in solutions. Exemplary dispersing agents include, without limitation, synthetic or naturally occurring detergents having nonionic or anionic surfactant activities such as: alkylaryl polyether alcohols, e.g. octylphenol-polyethylene glycol ether, commonly sold under the tradename, Triton® X-100 (hereinafter referred to as “TX-100”) (Sigma-Aldrich, St. Louis, Mo.); phenylated polyethoxy ethanols, e.g. (nonylphenoxy) polyethoxy ethanol commonly sold as Nonidet P-40/NP-40 (Vysis, Inc., Downers Grove, Ill.)(hereinafter “NP-40”); polyoxyethylene sorbitol esters, e.g., TWEEN®, manufactured by ICI Americas, Inc., Bridgewater, N.J. and EMASOL™, manufactured by Kao Specialties Americas LLC, High Point, N.C.; sodium dodecyl sulfate (hereinafter “SDS”); and ammonium bromides and chlorides (e.g., cetyltrimethylammonium bromide, tetradecylammonium bromide and dodecylpyrimidium chloride). Other dispersing agents include, without limitation, naturally occurring emulsifying agents such as deoxycholates and deoxycholate-type detergents (e.g., taurocholic acid) and cyclodextrins (e.g., α-, β- or γ-cyclodextrin), chaotropic salts such as urea and guanidine, and ion paring agents such as sulfonic acids (e.g., 1-heptanesulfonic acid and 1-octane-sulfonic acid).

Naturally occurring emulsifying agents such as taurocholic acid and cyclodextrins are highly effective in solubilizing and dispersing GNR structures in water and in facilitating derivatization of the purified and isolated GNR structures. In particular, cyclodextrins have a three dimensional doughnut shaped orientation with a “torsional” structure composed of glucopyranose units. The “torsional” structure of a cyclodextrin molecule allows it to attract and encapsulate a GNR structure within its central hydrophobic region, even when physically altered from a round “doughnut” shape to a twisted “doughnut” shape, while maintaining an outer hydrophilic surface rendering the molecule soluble in aqueous solutions. The solubility of cyclodextrins in water may also be increased nearly tenfold by substitution of, for example, methyl or hydroxypropyl groups on the cyclodextrin molecule. Greater solubility of the cyclodextrin in water translates to a greater dispersion and isolation of individual GNR structures in solution.

Taurocholic acid (“TA”), which is exemplary of a suitable deoxycholate-type detergent capable of substantially dispersing GNR structures in solution, is produced naturally in mammalian liver tissue. It is also highly effective in facilitating biological derivatization of purified and isolated GNR structures because, like the cyclodextrins, TA has a molecular shape that allows a large surface area of GNR structures to be coated per molecule of TA. Typically, cyclodextrins and deoxycholates may be utilized to suitably disperse GNR structures according to the present invention in concentrations ranging from about 1 mg/ml to about 1000 mg/ml of the aqueous solution.

In the present invention, it is also possible to use DNA (deoxyribonucleic acid), RNA (ribonucleic acid) and/or proteins as a dispersant for dispersing the graphene nanoribbons GNR1 in the liquid medium.

Synthetic detergents suitable for use as a dispersant will typically have high surfactant activity. The amount of detergent or surfactant can vary over a broad range. In principle, the surfactant can be used in an amount which is below, above or equal to its critical micelle concentration (hereinafter “CMC”). If below its CMC, the amount of surfactant can be e.g. in the range of 0.5×CMC to 0.95×CMC. On the other hand, if above its CMC, the amount of surfactant can be as high as e.g. 10×CMC. These high surfactant detergents are capable of overcoming hydrophobic forces at the GNR surface/aqueous solution interface by coating the GNR structures to establish suitable solubility of the GNR structures in solution. As appreciated by those of skill in the art, the surfactant properties of a synthetic detergent or surfactant may be characterized in terms of a hydrophilic-lipophilic balance (hereinafter “HLB”), which provides a measurement of the amount of hydrophilic groups to hydrophobic groups present in a detergent molecule. In particular, synthetic detergents or surfactants that are suitable for use as dispersing agents here have an HLB value between about 7 and about 13.2.

Additionally, chaotropic salts (e.g., urea and guanidine) are typically utilized as dispersing agents in concentrations ranging from about 6 M to about 9 M in solution (wherein “M” refers to molarity), whereas ion pairing agents are typically utilized as dispersing agents in concentrations ranging from about 1 mM to about 100 mM in solution.

Suitable anionic surfactants are for example alkali, alkaline earth or ammonium salts of sulfonates, sulfates, phosphates, carboxylates, and mixtures thereof. Examples of sulfonates are alkylarylsulfonates, diphenylsulfonates, alpha-olefin sulfonates, lignine sulfonates, sulfonates of fatty acids and oils, sulfonates of ethoxylated alkylphenols, sulfonates of alkoxylated arylphenols, sulfonates of condensed naphthalenes, sulfonates of dodecyl- and tridecylbenzenes, sulfonates of naphthalenes and alkylnaphthalenes, sulfosuccinates or sulfosuccinamates. Examples of sulfates are sulfates of fatty acids and oils, of ethoxylated alkylphenols, of alcohols, of ethoxylated alcohols, or of fatty acid esters. Examples of phosphates are phosphate esters. Examples of carboxylates are alkyl carboxylates, and carboxylated alcohol or alkylphenol ethoxylates.

Suitable nonionic surfactants are for example alkoxylates, N-substituted fatty acid amides, amine oxides, esters, sugar-based surfactants, polymeric surfactants, and mixtures thereof. Examples of alkoxylates are compounds such as alcohols, alkylphenols, amines, amides, arylphenols, fatty acids or fatty acid esters which have been alkoxylated with 1 to 50 equivalents. Ethylene oxide and/or propylene oxide may be employed for the alkoxylation, preferably ethylene oxide. Examples of N-substituted fatty acid amides are fatty acid glucamides or fatty acid alkanolamides. Examples of esters are fatty acid esters, glycerol esters or monoglycerides. Examples of sugar-based surfactants are sorbitans, ethoxylated sorbitans, sucrose and glucose esters or alkylpolyglucosides. Examples of polymeric surfactants are homo- or copolymers of vinylpyrrolidone, vinylalcohols, or vinylacetate.

Suitable cationic surfactants are for example quaternary surfactants, for example quaternary ammonium compounds with one or two hydrophobic groups, or salts of long-chain primary amines.

Suitable amphoteric surfactants are e.g. alkylbetains and imidazolines.

Suitable block copolymers acting as a dispersant are e.g. block copolymers of the A-B or A-B-A type comprising blocks of polyethylene oxide and polypropylene oxide, or of the A-B-C type comprising alkanol, polyethylene oxide and polypropylene oxide.

Suitable polyelectrolytes acting as a dispersant are e.g. polyacids or polybases. Examples of polyacids are alkali salts of polyacrylic acid or polyacid comb polymers. Examples of polybases are polyvinylamines or polyethyleneamines (also known as polyethyleneimines, i.e. a polymer having amine groups in the polymer chain).

The dispersant molecules typically surround individual GNR structures and efficiently separate those structures from bundles or stacks of ribbons in solution and act as spacer between individually dispersed GNR to prevent their reagglomeration.

The one or more contaminants are either not interacting with the dispersant(s) or show a level of interaction with the dispersant(s) which is different from the level of interaction between the graphene nanoribbons GNR1 and the dispersant(s).

Typically, the interaction between the contaminants which are not graphene nanoribbons and the dispersant(s) is quite weak so that these contaminants flocculate spontaneously in the liquid dispersant medium or can easily be separated from the liquid phase by appropriate separation steps such as centrifugation.

The GNR1-containing composition to be purified may also contain at least one contaminant which is interacting with the dispersant(s) sufficiently strong so as to be dispersed in the liquid medium. As already discussed above, the composition to be purified may contain graphene nanoribbons GNR2 which were generated as a by-product during the preparation of the graphene nanoribbons GNR1 and have one or more undesired properties in view of the intended final use (e.g. in electronic devices). However, as the interaction between this type of contaminant (e.g. GNR2) and the dispersant(s) is different from the interaction between the “target” graphene nanoribbons GNR1 and the dispersant(s), a separation of these dispersed fractions is possible, as will be discussed below in further detail.

Due to the strong interaction between the graphene nanoribbons GNR1 and the dispersant, the graphene nanoribbons GNR1 are dispersed in the liquid medium, and a liquid dispersion of the graphene nanoribbons GNR1 is obtained.

Dispersing the graphene nanoribbons GNR1 in the liquid medium can be supported or facilitated by appropriate treatment steps known to the skilled person. In a preferred embodiment, the graphene nanoribbons GNR1 are dispersed in the liquid medium under stirring, mechanical agitation, ultra-sonication, heating, milling, or any combination of these treatment steps.

Ultrasonication is commonly known to the skilled person and may include e.g. bath ultrasonication, probe ultrasonication and/or cup-horn ultrasonication. The intensity (i.e. energy input) of the ultrasonic treatment can vary over a broad range. In the present invention, it is possible to apply a high intensity ultrasonic treatment such as probe ultrasonication and/or cup-horn ultrasonication. In particular when using graphene nanoribbons of well-defined structure (preferably a structure defined by a repeating unit RU), it has been realized that a high intensity ultrasonic treatment and/or an ultrasonic treatment over a prolonged time period can be applied while leaving the GNR structure intact (i.e. no ribbon breakage or rupture). So, in a preferred embodiment, the graphene nanoribbons GNR1 are dispersed in the liquid medium under ultra-sonication, wherein the ultrasonication comprises a probe ultrasonication or a cup-horn ultrasonication or a combination thereof.

If the GNR1-containing composition results from a surface-assisted manufacturing method and therefore contains graphene nanoribbons GNR1 applied on a substrate, the liquid dispersant medium and the GNR1-containing composition are brought into contact under conditions which make sure that the graphene nanoribbons GNR1 are removed from the substrate surface. Releasing the graphene nanoribbons GNR1 from the substrate surface can be improved by appropriate treatment steps such as stirring, mechanical agitation, ultra-sonication (preferably a high intensity ultrasonic treatment such as probe ultrasonication and/or cup-horn ultrasonication), heating, or any combination of these treatment steps.

The amount of graphene nanoribbons GNR1 dispersed in the liquid medium can vary over a broad range, and may be as high as 100 mg or 50 mg of GNR1/ml of liquid dispersant medium.

As indicated above, the liquid dispersion of the graphene nanoribbons GNR1 is subjected to a separation treatment so as to at least partly remove the one or more contaminants, thereby obtaining a liquid dispersion of purified graphene nanoribbons GNR1.

The separation treatment may include one or more separation steps. Commonly known separation steps such as filtration, centrifugation, density gradient centrifugation (e.g. density gradient ultra-centrifugation), chromatography, electrophoresis, sedimentation, or any combination thereof can be applied.

As already indicated above, some contaminants are typically not dispersed in the liquid medium and therefore flocculate. The flocculated contaminants can be separated from the dispersed graphene nanoribbons GNR1 by filtration. By selecting a filter having an appropriate pore size or mesh size, the dispersed graphene nanoribbons run through the filter whereas the flocculated contaminants are collected on the filter. Depending on the type of contaminants to be separated and the graphene nanoribbons GNR1 to be purified, the filter pore size or mesh size may vary over a broad range, e.g. from 0.01 μm to 1.0 μm, more preferably from 0.05 μm to 0.5 μm, or from 0.1 μm to 0.4 μm.

Alternatively or in combination with the filtration, the liquid dispersion of the graphene nanoribbons GNR1 can be subjected to centrifugation. Those contaminants which are not sufficiently interacting with the dispersant will flocculate and sediment under centrifugation conditions, whereas the graphene nanoribbons GNR1 will remain in a dispersed state. Subsequently, the flocculated and sedimented contaminants can be separated from the supernatant dispersion, e.g. by filtration or decantation.

According to another preferred embodiment, the separation treatment includes a chromatography step. The dispersed graphene nanoribbons GNR1 remain in the liquid mobile phase, whereas at least some of the contaminants are adsorbed on the stationary phase. The separation principle may be based e.g. on size exclusion effects (gel permeation chromatography (GPC)) or polarity differences (HPLC) or combinations thereof. So, in a preferred embodiment, the separation treatment includes a gel permeation chromatography (GPC) step. The dispersed graphene nanoribbons GNR1 can thus be separated from contaminants that have a differing ‘effective size in solution’. According to another preferred embodiment, the separation treatment includes a high-performance liquid chromatography (HPLC) step.

According to another preferred embodiment, the separation treatment includes density gradient centrifugation. As known to the skilled person, the basic concept of density gradient centrifugation is that a mixture to be separated is placed onto the surface of a vertical column of liquid, the density of which progressively increases from top to bottom, and then centrifugation is started. Different kinds of density gradient centrifugation can be used in the present invention. Just as an example, rate-zonal separation can be used. As known to the skilled person, in rate-zonal separation, components of a mixture are separated based on their size and mass. This means that they migrate through the gradient according to these properties, which allows their separation into distinct zones or bands. Alternatively, isopycnic separation can be used. As known to the skilled person, in isopycnic separation the particles migrate through the liquid density gradient until they reach the point where their buoyant density is equal to that of the gradient. Separation via density gradient centrifugation might be of particular interest if at least one of the contaminants is well dispersed in the liquid medium but the degree of interaction between said contaminant and the dispersant is different from the degree of interaction between the graphene nanoribbons GNR1 and the dispersant. This may be the case if said contaminant is a graphene nanoribbon GNR2.

As a result of said one or more separation steps, a liquid dispersion of purified graphene nanoribbons GNR1 is obtained.

Optionally, the liquid dispersion of purified graphene nanoribbons GNR1 can be subjected to one or more post-treatment steps, e.g. for removing excess dispersant (such as dispersant not being adsorbed on the graphene nanoribbons GNR1). Such post-treatment steps include e.g. filtration with a small pore size or mesh size filter and re-dispersing in another liquid medium (preferably aqueous medium), chromatography, dialysis, or any combination thereof. In the post-treated liquid dispersion, the graphene nanoribbons GNR1 are still present in a dispersed state, i.e. coated with a dispersant.

According to a further aspect, the present invention provides a liquid dispersion of purified graphene nanoribbons GNR1, which is obtainable or obtained by the purification method described above.

As a result of the method described above wherein graphene nanoribbons GNR1 are dispersed in a first step in a liquid dispersant medium, followed by subjecting the GNR1 dispersion to one or more separation steps so as to obtain a purified GNR1 dispersion, individualized dispersant-coated graphene nanoribbons GNR1 are obtainable.

Thus, in a preferred embodiment, the liquid dispersion of purified graphene nanoribbons GNR1 comprises individualized dispersant-coated graphene nanoribbons GNR1.

An individualized graphene nanoribbon is not in direct contact with another graphene nanoribbon. In other words, each of the individualized graphene nanoribbons has its own dispersant coating which prevents it from coming into direct contact and aggregating with other non-dispersant-coated graphene nanoribbons. This does not exclude that the dispersant coatings of two individualized graphene nanoribbons may contact each other.

Whether or not individualized graphene nanoribbons have been formed can be verified by analytical methods known to the skilled person after deposition on a surface, such as atomic force microscopy, transmission electron microscopy, or scanning tunneling microscopy.

Preferably, at least 50% of the purified graphene nanoribbons GNR1 are individualized dispersant-coated graphene nanoribbons. More preferably, at least 80%, even more preferably at least 95% of the purified graphene nanoribbons GNR1 are individualized dispersant-coated graphene nanoribbons.

The amount of purified graphene nanoribbons GNR1 being present in the liquid dispersion may vary over a broad range. The liquid dispersion may contain the purified graphene nanoribbons GNR1 in an amount of e.g. from 0.0001 wt % to 10 wt % or 0.001 wt % to 5 wt %.

Depending on the type of dispersant and the properties of the graphene nanoribbon GNR1, the weight ratio of dispersant to purified graphene nanoribbons GNR1 may vary over a broad range, e.g. from 1/10 to 10000/1 or 1/10 to 1000/1 or 1/10 to 100/1.

According to a further aspect, the present invention provides a process for depositing graphene nanoribbons, which comprises:
providing a liquid dispersion of purified graphene nanoribbons GNR1 according to the process described above, and
depositing the purified graphene nanoribbons GNR1 on a substrate.

The graphene nanoribbons GNR1 can be deposited on the substrate by methods commonly known to the skilled person, such as spin coating, drop casting, zone casting, immersion coating, dip coating, blade coating, spraying, printing, or any combination thereof.

In some situations, it might be useful to immobilize or affix the GNRs to the surface of the substrate. This may be a first step in device fabrication or may be useful in GNR cutting methods.

The GNRs can be dried so as to affix them to the surface of the substrate. Alternatively, the GNRs can be dried prior to washing the surface. Drying can be accomplished by any means that does not damage the nanoribbons. One preferred method is by passing a stream of gas over the substrate. Any gas may be used that is not reactive with the substrate or nanoribbons.

After drying, the dispersant may be removed from the nanoribbons by any chemical or physical means that will preferentially degrade the dispersant, such as but not limited to plasma, etching, enzymatic digestion, chemical oxidation, hydrolysis, and heating. One preferred method is by heating. Alternatively the dispersant may be removed by solvent dissolving the dispersant but not the GNRs, such as water.

After the graphene nanoribbons are deposited and/or aligned on the substrate, the nanoribbons may be cut to a uniform length. Methods that can be used to cut the nanoribbons include but are not limited to the utilization of ionized radiation including photon irradiation utilizing ionized radiation such as ultraviolet rays, X-rays, electron irradiation, ion-beam irradiation, plasma ionization, and neutral atoms machining, optionally through a photomask or a photoresist mask with a specific pattern.

Preferably, the substrate on which the purified graphene nanoribbons are deposited is a substrate of an electronic, optical or optoelectronic device. Exemplary devices include e.g. field effect transistors, photovoltaic devices, sensor devices or light-emitting devices.

Substrates useful in the present invention may comprise silicon, silicon dioxide, glass, metal, metal oxide, metal nitride, metal alloy, polymers, ceramics, and combinations thereof. Particularly suitable substrates will be comprised of for example, quartz glass, fused silica, alumina, graphite, mica, mesoporous silica, silicon wafer, nanoporous alumina, silica, titania, ZnO₂, HfO₂, SnO₂, Ta₂O₃, TaN, SiN, Si₃N₄, Al₂O₃, and ceramic plates. Preferably, the substrate is quartz glass or silicon wafer coated with one of the aforementioned isolators.

Optionally it may be useful to modify the surface of the solid substrate so that it will better receive and bind the nano-structures. For example the solid substrate, especially metal oxide surfaces, may be pre-treated, microetched or may be coated with materials for better nanostructure adhesion, alignment or to yield a cleaner interface between the surface and the nano-structure. Methods for coating SiO₂ and other oxide surfaces, e.g. with aminosilanes, alkylsilanes, or phosphonic acids, are known to the skilled person. Dispersed GNR will have better adhesion to hydrophobic surface structures and hydrophopization of the surface may thus be preferred.

As already discussed above, the liquid dispersion of purified graphene nanoribbons GNR1 may comprise individualized dispersant-coated graphene nanoribbons GNR1. Accordingly, with the method described above, it is possible to deposit individualized graphene nanoribbons on a substrate of e.g. an electronic, optical or optoelectronic device. Depending on the amount of purified graphene nanoribbons GNR1 in the liquid dispersant, the individualized dispersant-coated graphene nanoribbons being deposited on the substrate can be spaced apart from each other, or may be in contact via their dispersant coatings).

The deposition of an individual GNR in discrete and individual form on a surface allows using the individual GNR in an electronic device, e.g. in a transistor device.

When using dispersions of higher GNR concentration, the deposited GNR structures typically form substantially longitudinally aligned and substantially parallel “raft-like” or tape structures that are free of any contaminants. As used herein, “raft-like” or “tape” refers to arrays of nanoribbons arranged in various geometrically ordered configurations, including configurations where individual nanoribbons are placed generally parallel with respect to each other to form structures of monolayer or multi-layer thicknesses. The alignment of GNR structures into substantially parallel “rafts” occurs due to repulsive forces induced by the dispersing agent coated surfaces of the structures. The highly ordered and separated alignment of individual nanoribbons facilitates easy characterization and manipulation of the GNR structures.

Another method for forming “raft-like” GNR structures is to immobilize the structures on a poly-hydroxylated surface. For example, dispersing agent coated GNR structures may be deposited on a surface coated with polyethylene glycol, e.g., a low molecular weight polyethylene glycol (“PEG”) such as CarboWax® (Dow Chemical Co., South Charleston, W. Va.). Subsequent analysis reveals that the GNR structures remain in isolated form.

According to a further aspect, the present invention provides an electronic, optical or optoelectronic device, obtainable or obtained by the graphene nanoribbon deposition process described above.

Preferably, the device comprises a substrate on which individualized graphene nanoribbons are deposited. The individualized graphene nanoribbons can be dispersant-coated (i.e. have a dispersant coating). Alternatively, it is possible that the dispersant coating has been removed, e.g. by thermal treatment and/or solvent treatment, thereby resulting in non-coated individualized graphene nanoribbons. However, as these graphene nanoribbons are adsorbed on a solid substrate, they remain individualized (i.e. no direct contact between the graphene nanoribbons) even after removal of the dispersant coating.

According to a further aspect, the present invention provides a device, which comprises a single graphene nanoribbon GNR1, or two or more graphene nanoribbons GNR1 which do not contact each other, the graphene nanoribbon(s) GNR1 comprising a repeating unit.

The device can be an electronic device, an optical device or an optoelectronic device. Exemplary devices include field-effect transistors, photovoltaic devices, sensor devices, or light-emitting devices.

With regard to the preferred properties of graphene nanoribbons GNR1 comprising a repeating unit and appropriate manufacturing methods of such graphene nanoribbons by chemical bottom-up processes, reference can be made to the statements provided above.

Accordingly, the graphene nanoribbons GNR1 have a repeating unit which is preferably derived from at least one polycyclic aromatic monomer compound, and/or from at least one oligophenylene aromatic monomer compound. As already mentioned above, the graphene nanoribbons GNR1 having a repeating unit are preferably obtained or obtainable by forming a precursor polymer from at least one polycyclic aromatic monomer compound and/or at least one oligophenylene aromatic monomer compound, followed by subjecting the precursor polymer to a cyclodehydrogenation.

As already discussed above, the graphene nanoribbon(s) GNR1 may still be coated with a dispersant (e.g. a surfactant) which originates from the purification process described above. Alternatively, it may be preferred that the dispersant has been removed from the graphene nanoribbons GNR1 after deposition on the substrate, i.e. the device comprises dispersant-free graphene nanoribbons GNR1.

If each of the two or more graphene nanoribbons GNR1 is still coated with a dispersant, contact between the graphene nanoribbons is avoided by these dispersant coatings. As the graphene nanoribbons GNR1 are adsorbed on a solid substrate, they remain “individualized” and do not contact each other even after removal of the dispersant coating.

In a preferred embodiment, the device is a field-effect transistor or a device comprising two or more field-effect transistors.

Like any field-effect transistor, the field-effect transistor of the present invention comprises a drain electrode and a source electrode. Preferably, the drain electrode and the source electrode are connected either by the single graphene nanoribbon GNR1, or by the two or more graphene nanoribbons GNR1. If the drain electrode and the source electrode are connected by the two or more individualized graphene nanoribbons GNR1, it is preferred that each graphene nanoribbon GNR1 is connected to (i.e. in contact with) the drain electrode and the source electrode. More preferably, the drain electrode and the source electrode are connected by the single graphene nanoribbon GNR1, i.e. in between the drain electrode and the source electrode, there is just one graphene nanoribbon GNR1. This single graphene nanoribbon acts as a channel for the transport of charge carriers (electrons) between the drain and source electrodes.

Appropriate materials for the drain electrode and the source electrode are commonly known to the skilled person. Exemplary electrode materials include metals, nanocarbons (e.g. carbon nanotubes or graphene), doped or undoped inorganic semiconductors. Appropriate metals are transition metals, e.g. noble metals such as Pd, Pt, Au, Ag, Cu or any alloy thereof such as Pd/Au alloys, or other transition metals such as Ti, Ni or Al. Inorganic semiconductors are Si, Ge, with or without dopants, can also be used as an electrode material. The drain electrode and the source electrode may be doped or undoped. The drain electrode and the source electrode may comprise the same electrode material. Alternatively, the drain and source electrodes may comprise different materials. For improving adhesion of the drain and source electrodes on the substrate, an adhesion-promoting component (e.g. a metal such as Ti) can be applied in between the substrate and the electrodes.

Depending on the length of the graphene nanoribbon GNR1 acting as a channel between source and drain, the gap length between the drain and source electrodes (i.e. the shortest distance between the end of the drain electrode and the end of the source electrode) may vary over a broad range. Typically, the gap length (e.g. determined by atomic force microscopy AFM) is less than the length of the one or more graphene nanoribbons which are connecting drain and source electrodes. So, typically both on the drain side and the source side there is an overlap area between the electrodes and the graphene nanoribbon(s). The gap length can be e.g. from 5 nm to 10 μm, or from 10 nm to 100 nm.

Appropriate substrates on which the drain and source electrodes and the channel connecting these electrodes (i.e. the graphene nanoribbon) can be applied are those which are commonly known to the skilled person. Just as an example, the substrate may comprise silicon on which optionally one or more layers of a dielectric material (e.g. silica or alumina) are applied. Optionally, the surface of the substrate may at least partially be covered by a hydrophobic surface layer so as to improve interface between the graphene nanoribbons and the substrate surface and to create a contrast in surface energy between areas in which the GNRs should stick during deposition (in the area where the source and drain contacts will be patterned) and hydrophilic areas. This is commonly known to the skilled person.

Just like any field-effect transistor, the field-effect transistor of the present invention has a gate electrode. The field-effect transistor can have a so-called “back-gated configuration” wherein the substrate comprises the back gate. Alternatively, a dielectric layer which is at least partly covering the graphene nanoribbon GNR1 can be deposited, and the gate applied on top of the dielectric, thereby achieving a so-called top-gate configuration.

The field-effect transistor described above can be prepared e.g. by
providing a substrate,
applying on the substrate at least one graphene nanoribbon GNR1 which comprises a repeating unit,
applying a drain electrode and a source electrode on the substrate, wherein the graphene nanoribbon GNR1 is contacting both the drain electrode and the source electrode.

With regard to the preferred properties of the graphene nanoribbon(s) GNR1, the substrate and the drain and source electrodes, reference can be made to the statements provided above.

Preferably, the one or more graphene nanoribbons GNR1 are applied onto the substrate by bringing the substrate into contact with the liquid (preferably aqueous) dispersion of purified graphene nanoribbons GNR1 described above. As mentioned above, the liquid dispersion of purified graphene nanoribbons preferably comprises individualized dispersant-coated (e.g. surfactant-coated) graphene nanoribbons. The liquid dispersion and the substrate can be brought into contact by methods commonly known to the skilled person, such as spin coating, drop casting, zone casting, immersion coating, dip coating, blade coating, spraying, printing, or any combination thereof. After having applied the The drain and source electrodes can be applied onto the substrate by methods which are commonly known to the skilled person, such as lithographic methods (e.g. e-beam lithography).

As already discussed above, the drain and source electrodes can be applied onto the substrate such that the drain electrode and the source electrode are connected by a single graphene nanoribbon GNR1. Alternatively, the drain electrode and the source electrode can be connected by two or more graphene nanoribbons GNR1 which do not contact each other. If the drain electrode and the source electrode are connected by the two or more individualized graphene nanoribbons GNR1, it is preferred that each graphene nanoribbon GNR1 is connected to (i.e. in contact with) the drain electrode and the source electrode. More preferably, the drain electrode and the source electrode are connected by the single graphene nanoribbon GNR1, i.e. in between the drain electrode and the source electrode, there is just one graphene nanoribbon GNR1.

If the device is a device comprising two or more field-effect transistors, they can be provided on a single substrate. Alternatively, the two or more field-effect transistors can be provided on separate substrates.

By using a graphene nanoribbon of well-defined structure (i.e. comprising a repeating unit and prepared by a chemical “bottom-up” synthesis approach) as a channel between source and drain electrodes of a field-effect transistor, excellent control of the electronic properties of the device can be achieved.

Furthermore, as these graphene nanoribbons of well-defined structure (defined by a repeating unit) obtainable by bottom-up synthesis show an extremely high structural uniformity, a plurality of field-effect transistors made of more or less identical components (in particular identical channels connecting drain and source electrodes) can be manufactured.

The present invention is now described in further detail by the following examples.

### EXAMPLES

### Graphene Nanoribbons GNR1 Used for Making Graphene Nanoribbon Dispersions

Structurally defined graphene nanoribbons are prepared according to synthetic procedures described in literature.

Method (A):

Following Example 7 of WO 2013/093756, a composition comprising graphene nanoribbons GNR1 and unavoidable contaminants resulting from said manufacturing method was prepared in a solution based process via cyclodehydrogenation of a precursor polymer. The liquid reaction medium was subjected to a filtration step (i.e. a purification pre-treatment) and the GNR-containing composition to be purified was obtained in the form of a powder.

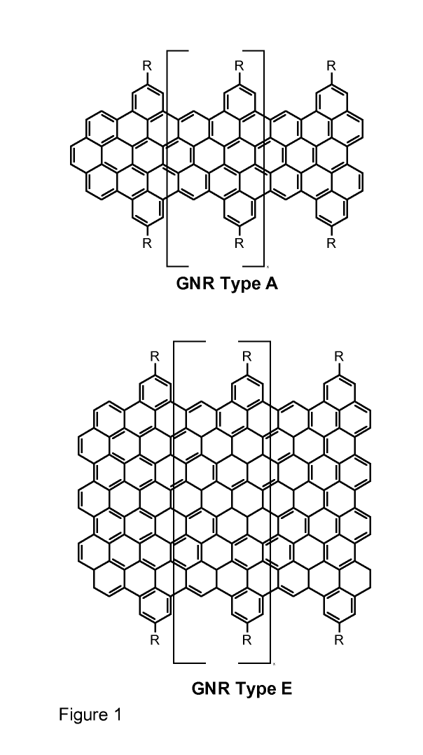

The structure of this type of graphene nanoribbon is shown in FIG. 1 (in the following referred to as GNR structure type (A)). The part of the GNR structure representing the repeating unit RU is shown in FIG. 1 as well.

Method (B):

Following the preparation method described in J. Am. Chem. Soc. 2008, 130, 4216, a composition comprising graphene nanoribbons GNR1 and unavoidable contaminants resulting from said preparation method was provided by a solution-based process. The liquid reaction medium was subjected to a filtration step (i.e. a purification pre-treatment) and the GNR-containing composition to be purified was obtained in the form of a powder.

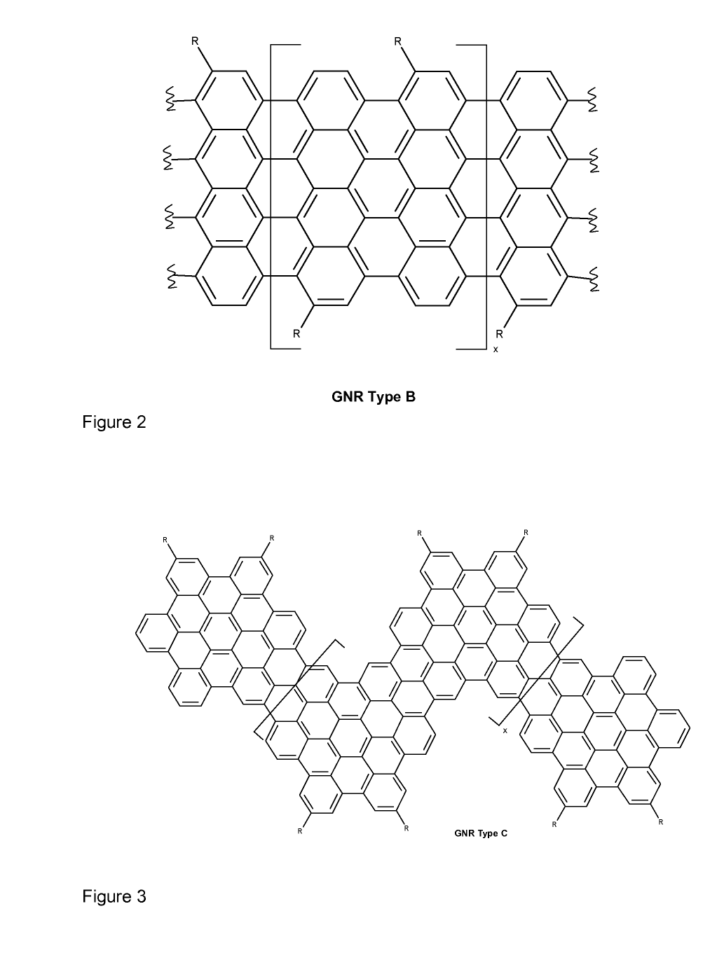

The structure of the type of graphene nanoribbons prepared via Methods (B) is shown in FIG. 2 (in the following referred to as GNR structure type (B)). The part of the GNR structure representing the repeating unit RU is shown in FIG. 2 as well.

Method (C):

Following the surface-assisted preparation method described in Nature 466, 470-473 (2010), a composition comprising the target graphene nanoribbons GNR1 and unavoidable contaminants resulting from said preparation method is provided on a substrate surface. As the substrate is inconsistent with the intended application of the graphene nanoribbons in electronic devices, it also represents a contaminant to be separated from the graphene nanoribbons.

The structure of the type of graphene nanoribbons prepared via Methods (C) is shown in FIG. 3 (in the following referred to as GNR structure type (C)). The part of the GNR structure representing the repeating unit RU is shown in FIG. 3 as well.

Method (D):

Following the surface-assisted preparation method described in Nature 466, 470-473 (2010), a composition comprising the target graphene nanoribbons GNR1 and unavoidable contaminants resulting from said preparation method is provided on a substrate surface. As the substrate is inconsistent with the intended application of the graphene nanoribbons in electronic devices, it also represents a contaminant to be separated from the graphene nanoribbons.

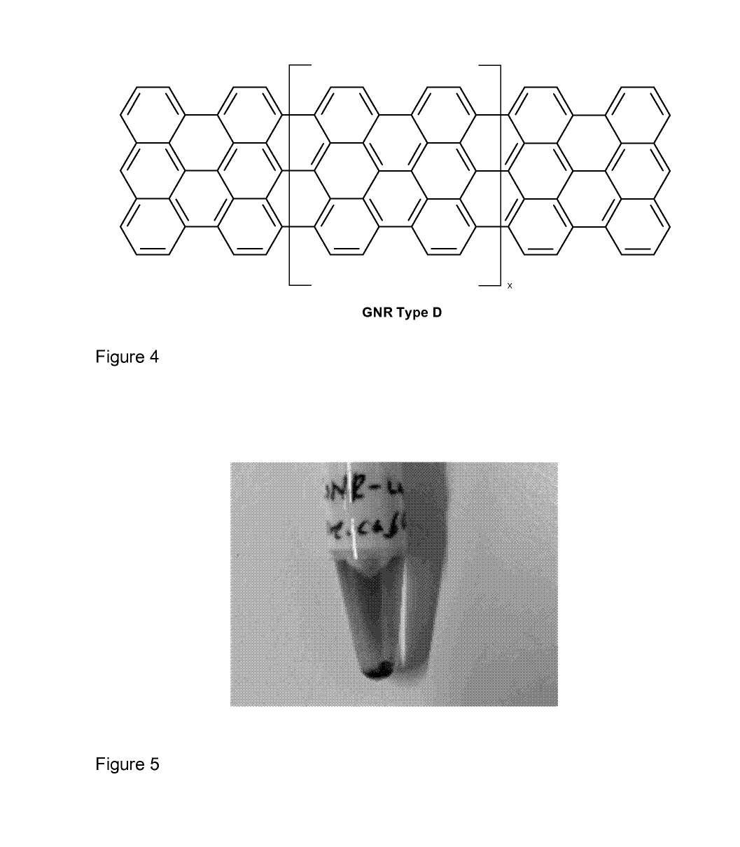

The structure of the type of graphene nanoribbons prepared via Method (D) is shown in FIG. 4 (in the following referred to as GNR structure type (D)). The part of the GNR structure representing the repeating unit RU is shown in FIG. 4 as well.

Method (E):

Following Example 6.3.11.8 of ‘Bottom-up Solution Synthesis of Structurally Defined Graphene Nanoribbons’ (Akimitsu Narita, Dissertation, University Mainz, 2014), a composition comprising graphene nanoribbons GNR1 and unavoidable contaminants resulting from said manufacturing method was prepared in a solution based process via cyclodehydrogenation of a precursor polymer. The liquid reaction medium was subjected to a filtration step (i.e. a purification pre-treatment) and the GNR-containing composition to be purified was obtained in the form of a powder.

The structure of this type of graphene nanoribbon is shown in FIG. 1 (in the following referred to as GNR structure type (E)). The part of the GNR structure representing the repeating unit RU is shown in FIG. 1 as well.

The target graphene nanoribbons to be isolated from the GNR-containing compositions are listed in Table 1.

TABLE 1
Graphene nanoribbons to be purified

| | Preparation | | | |
|---|---|---|---|---|
| | method of GNR- | GNR | Mol. | |
| Example | containing | Structure | Weight | |
| No. | composition | Type | (M_{w}) | R |
| 1 | solution | A | 600′000 | C₁₂H₂₅ |
| 2 | solution | A | 600′000 | C₁₂H₂₅ |
| 3 | solution | A | 60′000 | C₁₂H₂₅ |
| 4 | solution | A | 60′000 | C₁₂H₂₅ |
| 5 | solution | B | 8′000 | C₁₂H₂₅ |
| 6 | solution | B | 14′000 | C₁₂H₂₅ |
| 7 | surface | C | 20′000 | H |
| 8 | surface | D | 14′000 | H |
| 9 | solution | E | 420′000 | C₁₂H₂₅ |

Preparation of Purified GNR Dispersions

The following commercially available dispersants were used:
a) Sodium dodecyl sulfate (SDS) (Sigma-Aldrich), an anionic surfactant
b) Hexadecyltrimethylammonium bromide (CTAB) (Sigma-Aldrich), a cationic surfactant
c) Lupasol PN60 (BASF), a polybase having amine groups in the polymer chain (i.e. a polyelectrolyte)
d) Pluronic PE10500 (BASF), a non-ionic surfactant
e) Tamol NN9401 (BASF), a polyelectrolyte
f) Pluronic PE6800 (BASF), a non-ionic surfactant
g) Sodium dodecyl benzene sulfonate (SDBS) (Sigma-Aldrich), an anionic surfactant

For preparing purified GNR dispersions, the following general procedure was applied:

A solution of dispersant in DI water was added to the GNR-containing composition. Following a 20 pulse tip-sonication, the sample was placed into an Ultrasonic bath for 2 hours. An aqueous dispersion of the graphene nanoribbons GNR1 was obtained.

Subsequently, the solution was centrifuged for 3 min at 10000 rpm. The contaminants sedimented whereas the graphene nanoribbons GNR1 remained in a dispersed state. The purified graphene nanoribbons can be separated from the sedimented contaminants e.g. by decantation.

FIG. 5 shows a centrifuge tube after centrifugation of the GNR1-containing dispersion. As can be seen from FIG. 5, the contaminants have sedimented. The dispersant-coated graphene nanoribbons GNR1 remain in the liquid dispersion and can then be deposited on a substrate, thereby providing uniform GNR structures on a surface (e.g. of an electronic device), as will be described below.

Subsequently, these purified GNR dispersions were used for depositing the target GNR on a substrate. For depositing purified GNR on a substrate, the following general procedures were applied:

Degenerately doped silicon wafers coated with 30 nm of ALD (atomic layer deposited) Al₂O₃ and functionalized with n-octadecylphosphonic acid were used as substrate for deposition. Deposition of the GNRs was done using two different methods:

1.) Substrates were immersed for 12 h into the purified GNR dispersion. After removal of the samples from the solution, the samples were blowdried under a nitrogen stream, subsequently rinsed with DI-water and blowdried again.

2.) Substrates were placed on a hotplate at 120° C. in ambient condition. The purified GNR dispersion was dropcast onto the hot substrate. Subsequently the substrate was rinsed with DI-water and then blowdried.

### Example 1

### Dispersion of a GNR Type A and Deposition of Purified GNR on a Substrate by Immersion

1 wt % SDS (sodium dodecyl sulfate)/DI water solution was added to the GNR powder. A purified GNR dispersion was prepared according to the general procedure described above.

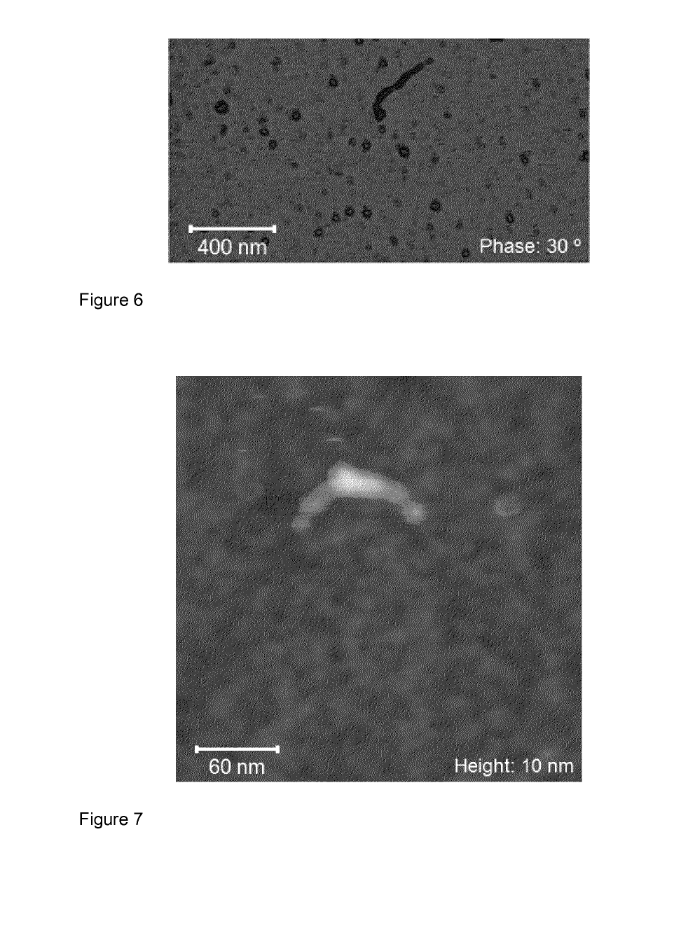

GNR deposition on a surface was performed according to general deposition procedure 1 described above. FIG. 6 shows an atomic force microscopy image of the substrate surface. As can be seen from FIG. 6, an individual isolated graphene nanoribbon with a length of about 500 nm is present on the substrate surface. With the purification method of the present invention, it is possible to provide isolated dispersant-coated graphene nanoribbons which are individually dispersed in the purified GNR dispersion. If such a purified GNR dispersion is applied onto a substrate, followed by removal of the liquid dispersion medium, individual graphene nanoribbons are provided on said substrate.

### Example 2

### Dispersion of a GNR Type A and Deposition of Purified GNR on a Substrate by Drop Casting

A purified GNR dispersion is prepared as in example 1.

Deposition of purified GNRs on a surface was performed according to general deposition procedure 2 described above.

### Example 3

### Dispersion of a GNR Type A and Deposition of Purified GNR on a Substrate by Immersion

1 wt % SDS (sodium dodecyl sulfate)/DI water solution was added to the GNR powder. GNR dispersion was prepared according to the general procedure described above.

Purified GNRs were deposited on a surface according to the general deposition procedure 1 described above.

### Example 4

### Dispersion of a GNR Type A and Deposition of Purified GNR on a Substrate by Drop Casting

The graphene nanoribbons GNR1 used in Example 4 have a length of about 60 nm. The composition containing these graphene nanoribbons is subjected to the purification treatment described above.

A purified GNR dispersion is prepared as in example 3.

Deposition of GNRs on a surface was performed according to general deposition procedure 2 described above. FIG. 7 shows an atomic force microscopy image of the substrate surface. As can be seen from FIG. 7, an individual isolated graphene nanoribbon with a length of about 60 nm is present on the substrate surface (which corresponds to the length of the target graphene nanoribbons being present in the starting composition to be purified). With the purification method of the present invention, it is possible to provide isolated dispersant-coated graphene nanoribbons which are individually dispersed in the purified GNR dispersion. If such a purified GNR dispersion is applied onto a substrate, followed by removal of the liquid dispersion medium, individual graphene nanoribbons are provided on said substrate. Furthermore, as demonstrated by Example 4, the structure of the target graphene nanoribbons GNR1 is left intact (same ribbon length after deposition, i.e. no ribbon rupture or breakage) even if subjected to a high intensity sonication during the dispersion step.

### Example 5

### Dispersion of GNR Types A, B and E, and Deposition of Purified GNR on a Substrate by Immersion

The examples were performed in analogy to Example 1 by using different types of dispersants instead of SDS or different types of GNR and are listed below in Table 2.

TABLE 2
GNRs and dispersants used in Example 5

| | | | Mol. | | |
|---|---|---|---|---|---|
| Example | GNR | GNR | Weight | | |
| No. | Preparation | Type | (M_{w}) | R | Dispersant |
| 5A | solution | A | 600′000 | C₁₂H₂₅ | cationic surfactant |
| | | | | | (CTAB) |
| 5B | solution | A | 600′000 | C₁₂H₂₅ | Polyelectrolyte |
| | | | | | (Lupasol PN60) |
| 5C | solution | A | 600′000 | C₁₂H₂₅ | non-ionic surfactant |
| | | | | | (Pluronic PE10500) |
| 5D | solution | A | 600′000 | C₁₂H₂₅ | polyelectrolyte |
| | | | | | (Tamol NN9401) |
| 5E | solution | A | 600′000 | C₁₂H₂₅ | non-ionic surfactant |
| | | | | | (Pluronic PE6800) |
| 5F | solution | A | 600′000 | C₁₂H₂₅ | anionic surfactant |
| | | | | | (SDBS) |
| 5G | solution | B | 14′000 | H | anionic surfactant |
| | | | | | (SDS) |
| 5H | solution | E | 420′000 | C₁₂H₂₅ | anionic surfactant |
| | | | | | (SDS) |

GNR deposition on a surface was performed according to general deposition procedure 1 described above. Atomic force microscopy of the substrate surface showed individual isolated graphene nanoribbons present on the substrate surface. With the purification method of the present invention, it is possible to provide isolated dispersant-coated graphene nanoribbons which are individually dispersed in the purified GNR dispersion. If such a purified GNR dispersion is applied onto a substrate, followed by removal of the liquid dispersion medium, individual graphene nanoribbons are provided on said substrate.

### COMPARATIVE EXAMPLES

The graphene nanoribbons used in the Comparative Examples are listed below in Table 3.

TABLE 3
GNRs used in the Comparative Examples

| Comparative | GNR | GNR | Mol. Weight | |
|---|---|---|---|---|
| Example No. | Preparation | Type | (M_{w}) | R |
| C1 | solution | A | 600′000 | C₁₂H₂₅ |
| C2 | solution | A | 600′000 | C₁₂H₂₅ |
| C3 | solution | A | 600′000 | C₁₂H₂₅ |
| C4 | solution | A | 600′000 | C₁₂H₂₅ |

Preparation of GNR Solution:

Chlorobenzene was added to the GNR powder. A clear solution was obtained.

Deposition of GNR on a Substrate:

Degenerately doped silicon wafers coated with 30 nm of ALD Al₂O₃ and functionalized with n-Octadecylphosphonic acid were used as substrate for deposition. Deposition of the GNRs was done using two different methods:

3.) Substrates were immersed for 24 h into the chlorobenzene GNR solution. After the removal of the samples from the solution the samples were blowdried under a nitrogen stream.

4.) Substrates were placed on a hotplate at the specified temperature in ambient condition. The GNR solution was dropcast onto the hot substrate. Subsequently the substrate was blowdried.

### Comparative Example C1

### Deposition of GNR Type A on a Substrate by Immersion

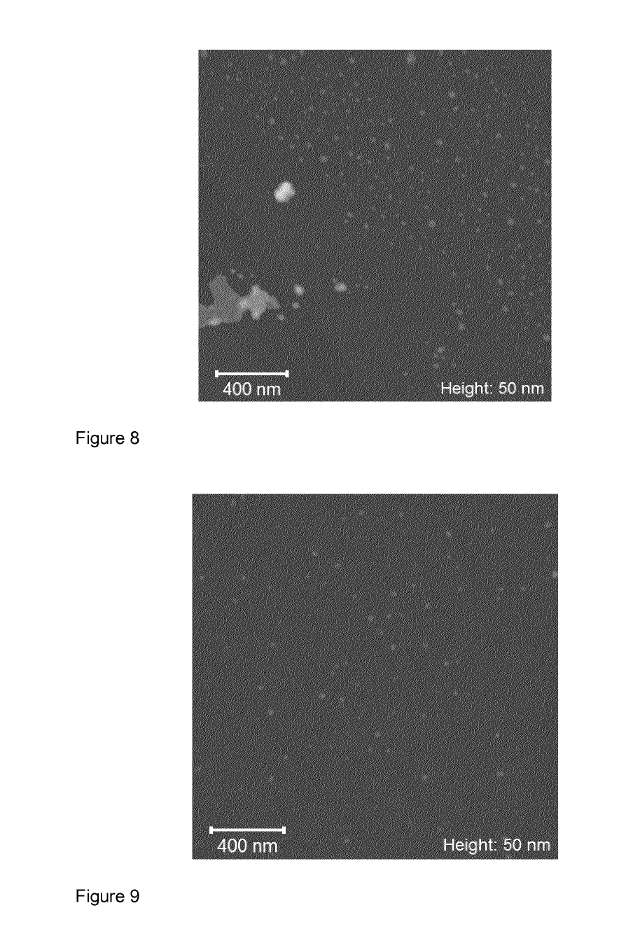

Deposition of GNRs on a surface was performed according to deposition procedure 3 described above. FIG. 8 shows an atomic force microscopy image of the substrate surface. No graphene nanoribbons can be seen.

### Comparative Example C2

### Deposition of GNR Type A on a Substrate by Drop Casting

Deposition of GNRs on a surface was performed according to deposition procedure 4 described above at 200° C. FIG. 9 shows an atomic force microscopy image of the substrate surface. No graphene nanoribbons can be seen.

### Comparative Example C3

### Deposition of GNR Type A on a Substrate by Drop Casting

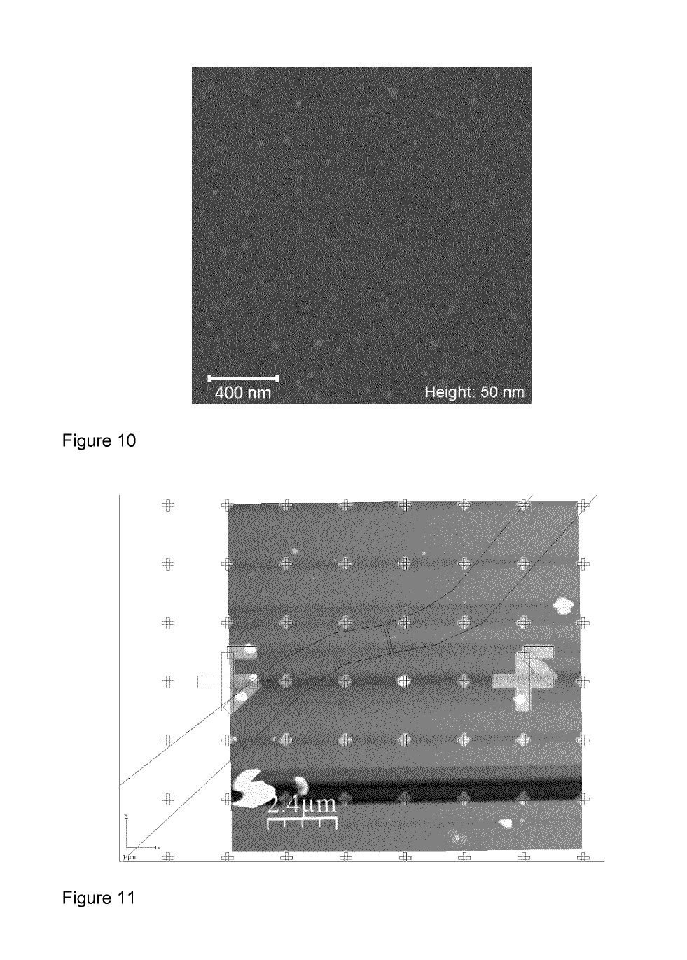

Deposition of GNRs on a surface was performed according to deposition procedure 4 described above at 150° C. FIG. 10 shows an atomic force microscopy image of the substrate surface. No graphene nanoribbons can be seen.

### Comparative Example C4

### Deposition of GNR Type A on a Substrate by Drop Casting

Deposition of GNRs on a surface was performed according to deposition procedure 4 described above at 90° C. Atomic force microscopy images of the substrate show no ribbon structures.

Preparation of a GNR Transistor Device:

a) Preparation of the Substrate:

In a first step, a Si wafer was coated with dielectric layers (a SiO₂ layer was applied first, followed by applying a Al₂O₃ layer). Additionally, metallic markers and electric pads were prepared by e-beam lithography on the substrate. When depositing the graphene nanoribbon on the substrate at a later stage and locating the deposited graphene nanoribbon together with neighboring markers by atomic force microscopy AFM, these markers are assisting in identifying the actual position of the graphene nanoribbon on the substrate. The dielectric coating layers, the markers and the contact pads were applied as follows:

Degenerately doped silicon wafers coated with 100 nm thermally grown SiO₂ and 8 nm Al₂O₃ grown with atomic layer deposition at 250° C. were used. Markers and contact pads were defined with electron beam lithography using a double layer PMMA resist, developed in MIBK/IPA 1:3 for 90 s and stopped in IPA for 60 s. In order to burn PMMA residues, a short oxygen plasma (200 w, 10 s) was applied. 5 nm Ti and 45 nm Au was deposited via thermal evaporation. Lift-off was performed in n-ethyl-2-pyrrolidon (NEP) for 2 hours at 65° C., subsequent rinsing with acetone and IPA. Samples were subsequently blow-dried with a nitrogen stream.

In order to enhance the quality of the GNR/dielectric interface, the surface was subsequently functionalized with a hydrophobic self-assembled monolayer (SAM). This was made as follows:

In order to allow lithography steps subsequent to SAM-deposition, the SAM-functionalization was confined to certain areas of the substrate by spin-coating a PMMA resist onto the entire substrate, and opening windows in the areas of the metal markers via e-ebeam lithography, development in MIBK/IPA 1:3 for 1 min (stopping of development in IPA for 60 s). Subsequently a short O2 plasma (200 W for 10 s) was applied in order to burn PMMA residues and to activate the surface for subsequent deposition of the SAM. The SAM was formed by immersing the substrate into a C₁₄H₂₉PO(OH)₂/IPA solution for one hour. Samples were subsequently rinsed with IPA and blow dried in a nitrogen stream. The PMMA mask was then removed.

b) Deposition of GNR on the Substrate Surface:

GNRs according to Example 1 of Table 1 were used. The GNRs were added to an aqueous dispersion medium containing 1 wt % sodium dodecyl sulfate (acting as an anionic surfactant). Following a 20 pulse tip-sonication, the sample was placed into an Ultrasonic bath for 2 hours. An aqueous dispersion of the graphene nanoribbons GNR1 was obtained.

Subsequently, the solution was centrifuged for 3 min at 10000 rpm. The contaminants sedimented whereas the graphene nanoribbons GNR1 remained in a dispersed state. The purified graphene nanoribbons were separated from the sedimented contaminants e.g. by decantation.

Subsequently, the purified GNR dispersion was used for depositing the GNR on the substrate. The substrate was immersed in the GNR suspension for 12 h. Subsequently, the sample was blow dried in a nitrogen stream, rinsed with water and IPA and blow dried in a nitrogen stream.

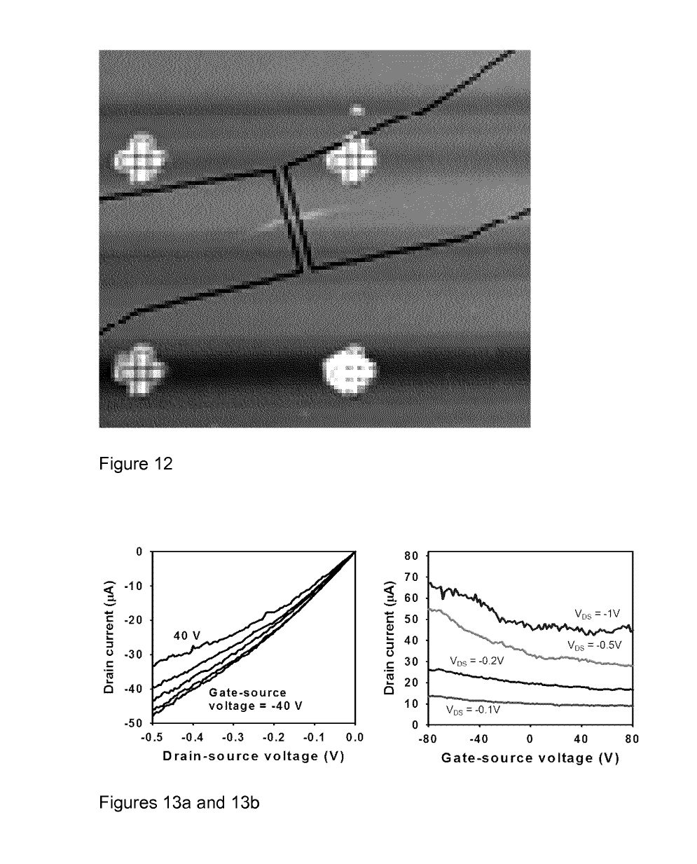

With atomic force microscopy, an area was identified in which a single graphene nanoribbon was deposited. This is shown in FIGS. 11 and 12 (FIG. 12 representing a magnification of the central area of FIG. 11). In these Figures, the areas on which the drain and source electrodes are deposited in the following step c) are already marked.

c) Formation of Metal Contacts to GNR:

In a further step, source and drain electrodes were applied onto the substrate by e-beam lithography. This was made as follows:

In order to pattern metal contacts with e-beam lithography onto individual nanoribbons, the GNRs were located relative to the predefined alignment markers with atomic-force microscopy (AFM) (see FIGS. 11 and 12). To pattern the metal contacts, PMMA 950K 2.5% was spin coated onto the sample. After e-beam lithography, samples were developed in MIBK/IPA 1:3 for 60 s. The development was stopped by immersing the substrates into IPA for 60 s. Metal contacts were then deposited via thermal evaporation (0.5 nm Ti and 30 nm AuPd (40/60)). Lift-off was performed as above.

As shown by FIGS. 11 and 12 (FIG. 12 being a magnification of the gap area between the drain and source electrodes), there is just a single graphene nanoribbon which is connecting the drain electrode and the source electrode.

d) Device Characterization:

Electrical measurements were performed with an Agilent 4155C on a probe station in air. Transfer and output characteristics are shown in FIGS. 13a and 13 b. Transistors are characterized by a high on current (48 μA at a drain-source voltage V_{DS} of −0.5 V) and a high saturation charge carrier mobility of 1000 cm²/Vs. Furthermore, in the output curve one can infer low contact resistance from the linear ID vs V_{DS} curve at small V_{DS} as well as current saturation at larger V_{DS}.

1. A process for purifying graphene nanoribbons, which comprises:
bringing into contact a composition comprising graphene nanoribbons GNR1 and at least one contaminant with a liquid medium comprising a dispersant, and dispersing the graphene nanoribbons GNR1 in the liquid medium so as to obtain a liquid dispersion of the graphene nanoribbons GNR1, and
subjecting the liquid dispersion of the graphene nanoribbons GNR1 to a separation treatment so as to at least partly remove the at least one contaminant, thereby obtaining a liquid dispersion of purified graphene nanoribbons GNR1.

2. The process according to claim 1, wherein the graphene nanoribbons GNR1 comprise a repeating unit, which is preferably derived from at least one of at least one polycyclic aromatic monomer compound and at least one oligophenylene aromatic monomer compound.

3. The process according to claim 2, wherein the graphene nanoribbons GNR1 are obtainable by forming a precursor polymer from at least one of the at least one polycyclic aromatic monomer compound and the at least one oligophenylene aromatic monomer compound, followed by subjecting the precursor polymer to a cyclodehydrogenation.

4. The process according to claim 1, wherein the at least one contaminant is at least one of non-reacted precursor molecules, non-reacted precursor polymers, polymeric reaction products having no graphene nanoribbon structure, agglomerates, metal residues, solid substrate materials, and any combination thereof.

5. The process according to claim 1, wherein the liquid medium is an aqueous medium.

6. The process according to claim 1, wherein the dispersant is selected from the group comprising: a surfactant, an emulsifying agent, a chaotropic salt, a block copolymer, a polyelectrolyte, a protein, deoxyribonucleic acid, ribonucleic acid, and any combination thereof.

7. The process according to claim 1, wherein the graphene nanoribbons GNR1 are dispersed in the liquid medium under ultrasonication.

8. The process according to claim 1, wherein the separation treatment comprises at least one of filtration, centrifugation, density gradient centrifugation, chromatography, electrophoresis, sedimentation, and any combination thereof.

9. A liquid dispersion of purified graphene nanoribbons, obtainable by the process according to claim 1.

10. The liquid dispersion according to claim 9, comprising individualized dispersant-coated graphene nanoribbons GNR1.

11. A process for depositing graphene nanoribbons, which comprises:
providing a liquid dispersion of purified graphene nanoribbons GNR1 according to claim 1, and
depositing the purified graphene nanoribbons GNR1 on a substrate.

12. The process according to claim 11, wherein the purified graphene nanoribbons GNR1 are deposited on the substrate by at least one of spin coating, drop casting, zone casting, immersion coating, dip coating, blade coating, spraying, printing, and any combination thereof.

13. The process according to claim 11, wherein the purified nanoribbons GNR1 are fixed to the substrate.

14. The process according to claim 11, wherein the substrate is a substrate of one of an electronic device, an optical device and an optoelectronic device.

15. A device, obtainable by the process according to claim 1; the device being one of an electronic device, an optical device and an optoelectronic device.

16. A device comprising one of a single graphene nanoribbon GNR1, and at least two graphene nanoribbons GNR1 which do not contact each other, each graphene nanoribbon GNR1 comprising a repeating unit; the device being one of an electronic device, an optical device and an optoelectronic device.

17. The device according to claim 16, wherein the repeating unit of each graphene nanoribbon GNR1 is derived from at least one of at least one polycyclic aromatic monomer compound and at least one oligophenylene aromatic monomer compound; each graphene nanoribbon(s) GNR1 being one of obtained and obtainable by forming a precursor polymer from at least one of the at least one polycyclic aromatic monomer compound and the at least one oligophenylene aromatic monomer compound, followed by subjecting the precursor polymer to a cyclodehydrogenation.

18. The device according to claim 16, wherein the device is a field-effect transistor comprising a drain electrode and a source electrode which are connected by one of the single graphene nanoribbon GNR1 and each of the at least two graphene nanoribbons GNR1.

19. The process according to claim 13, wherein the purified nanoribbons GNR1 are fixed to the substrate by thermal treatment.

20. The process according to claim 11, wherein the dispersant is removed from the purified graphene nanoribbons GNR1 after deposition on the substrate.
